(19) United States
(12) Patent Application Publication
(10) Pub. No.: US 2019/0206912 A1
(43) Pub. Date: Jul. 4, 2019

(54) IMAGE SENSOR, MICRO-LENS ARRAY, AND METHOD FOR FABRICATING MICRO-LENS ARRAY WITH DIFFERENT HEIGHTS IN IMAGE SENSOR

(71) Applicant: HIMAX TECHNOLOGIES LIMITED, Tainan City (TW)

(72) Inventors: Yu-Jui Hsieh, Tainan City (TW); Po-Nan Chen, Tainan City (TW)

(21) Appl. No.: 15/861,639

(22) Filed: Jan. 3, 2018

(51) Int. Cl. H01L 27/146; G02B 3/00

(52) U.S. Cl. CPC H01L 27/14605; H01L 27/14685; G02B 3/0018; H01L 27/14627

(57) ABSTRACT

The present invention provides an image sensor, a micro-lens array with different heights in a pixel size level in the image sensor, and a method for fabricating the micro-lens array with different heights in the pixel size level in the image sensor. The present invention uses three different optical masks to fabricate a micro-lens array with different heights in a pixel size level in an image sensor, and the micro-lens array with different heights in a pixel size level in the image sensor disclosed by the present invention is capable of providing the same depth of focus (or nearly the same depth of focus) for every photodiode in the image sensor with lower cost.

### BACKGROUND OF THE INVENTION

### 1. Field of the Invention

The present invention relates to an image sensor and a method of fabricating a micro-lens array, and more particularly, to an image sensor, a micro-lens array with different heights in a pixel size level in the image sensor, and a method for fabricating the micro-lens array with different heights in the pixel size level in the image sensor.

### 2. Description of the Prior Art

Please refer to FIGS. 1-2. FIGS. 1-2 are sectional diagrams illustrating sequential procedures of a conventional method for fabricating a micro-lens array 10 in an image sensor 100, wherein the image sensor 100 comprises a photodiode array 110, a pixel array 120, and a color filter array 130. As shown in FIG. 1, the pixel array 120 is disposed above the photodiode array 110, and each pixel of the pixel array 120 is corresponding to each photodiode of the photodiode array 110. The color filter array 130 is disposed above the pixel array 120, and red color filters 132, green color filters 134, and blue color filters 136 respectively corresponding to each pixel of the pixel array 120. Each of the red color filters 132 is corresponding to each pixel 122 of the pixel array 120 and each photodiode 112 of the photodiode array 110. Each of the green color filters 134 is corresponding to each pixel 124 of the pixel array 120 and each photodiode 114 of the photodiode array 110. Each of the blue color filters 136 is corresponding to each pixel 126 of the pixel array 120 and each photodiode 116 of the photodiode array 110. The conventional method forms a micro-lens material layer 140 on the color filter array 130, and utilizes an optical mask 150 to bleach the micro-lens material layer 140.

Next, as shown in FIG. 2, the conventional method reflows the bleached micro-lens material layer 140 to form the micro-lens array 10 having the same height. However, the micro-lenses of the micro-lens array 10 and the corresponding color filters of the color filter array 130 generate different depths of focus for the photodiodes 112, 114, 116 of the photodiode array 110. Thus, the image sensor 100 in the prior art has a poor imaging quality. In addition, if the conventional method uses an optical mask with gray level to fabricate the micro-lens array, it will cost a lot of money and it is still very difficult to fabricate the micro-lens array with different heights in a pixel size level in the image sensor.

### SUMMARY OF THE INVENTION

It is therefore one of the objectives of the present invention to provide an image sensor, a micro-lens array with different heights in a pixel size level in the image sensor, and a method for fabricating the micro-lens array with different heights in the pixel size level in the image sensor, so as to solve the problem mentioned above.

In accordance with an embodiment of the present invention, a method for fabricating a micro-lens array with different heights in an image sensor is disclosed, wherein the image sensor has a color filter array comprising first color filters, second color filters, and third color filters respectively corresponding to each pixel and each photodiode of the image sensor. The method comprises: forming a micro-lens material layer on the color filter array; utilizing a first optical mask to bleach the micro-lens material layer corresponding to each first color filter above each pixel of the image sensor; utilizing a second optical mask to bleach the micro-lens material layer corresponding to each second color filter above each pixel of the image sensor; utilizing a third optical mask to bleach the micro-lens material layer corresponding to each third color filter above each pixel of the image sensor; and reflowing the bleached micro-lens material layer to form the micro-lens array having different heights.

In accordance with an embodiment of the present invention, a micro-lens array with different heights in an image sensor is disclosed, wherein the image sensor has a color filter array comprising first color filters, second color filters, and third color filters respectively corresponding to each pixel and each photodiode of the image sensor. The micro-lens array comprises: a first set of micro-lenses, a second set of micro-lenses, and a third set of micro-lenses. The first set of micro-lenses has a first adjustable height corresponding to each first color filter in a pixel size level. The second set of micro-lenses has a second adjustable height corresponding to each second color filter in the pixel size level. The third set of micro-lenses has a third adjustable height corresponding to each third color filter in the pixel size level, wherein the first adjustable height is higher than the second adjustable height, and the second adjustable height is higher than the third adjustable height.

In accordance with an embodiment of the present invention, an image sensor is disclosed. The image sensor comprises: a photodiode array, a pixel array, a color filter array, and a micro-lens array. The pixel array is disposed above the photodiode array, and each pixel of the pixel array is corresponding to each photodiode of the photodiode array. The color filter array is disposed above the pixel array, and has a first color filters, second color filters, and third color filters respectively corresponding to each pixel of the pixel array. The micro-lens array is disposed above the color filter array, and comprises: a first set of micro-lenses, a second set of micro-lenses, and a third set of micro-lenses. The first set of micro-lenses has a first adjustable height corresponding to each first color filter in a pixel size level. The second set of micro-lenses has a second adjustable height corresponding to each second color filter in the pixel size level. The third set of micro-lenses has a third adjustable height corresponding to each third color filter in the pixel size level, wherein the first adjustable height is higher than the second adjustable height, and the second adjustable height is higher than the third adjustable height.

Briefly summarized, the present invention can use three different optical masks to fabricate a micro-lens array with different heights in a pixel size level in an image sensor, and the micro-lens array with different heights in a pixel size level in the image sensor disclosed by the present invention is capable of providing the same depth of focus (or nearly the same depth of focus) for every photodiode in the image sensor with lower cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 are sectional diagrams illustrating sequential procedures of a conventional method for fabricating a micro-lens array in an image sensor.

FIGS. 3-7 are sectional diagrams illustrating sequential procedures of a method for fabricating a micro-lens array with different heights in an image sensor in accordance with an embodiment of the present invention.

FIG. 8 is sectional diagram showing the micro-lens array with different heights in a pixel size level in the image sensor is capable of providing the same depth of focus for every photodiode in the image sensor.

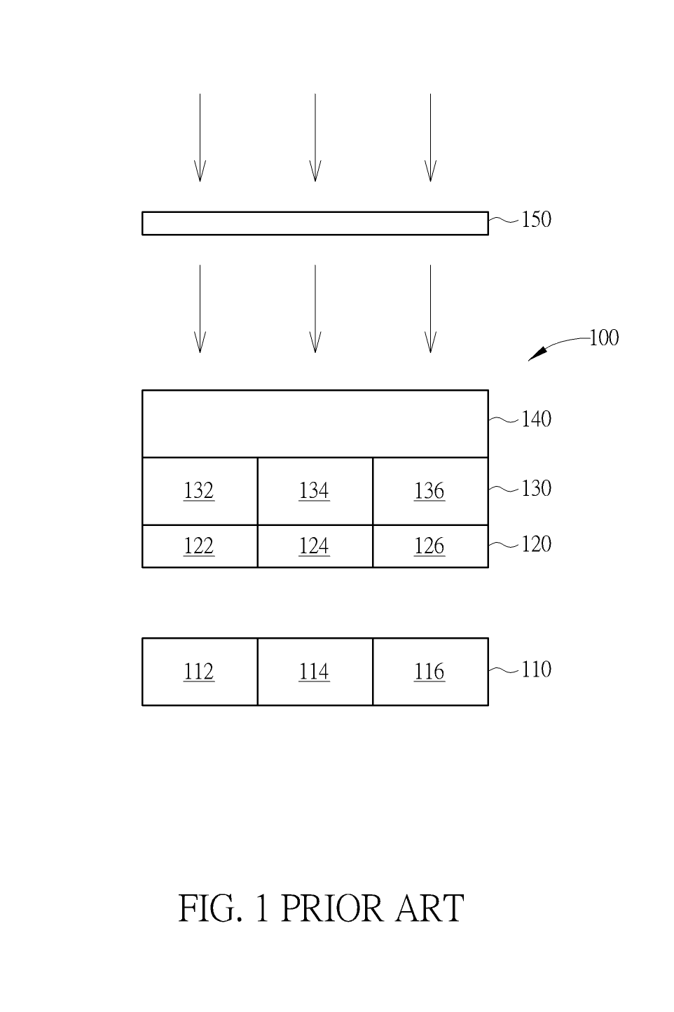

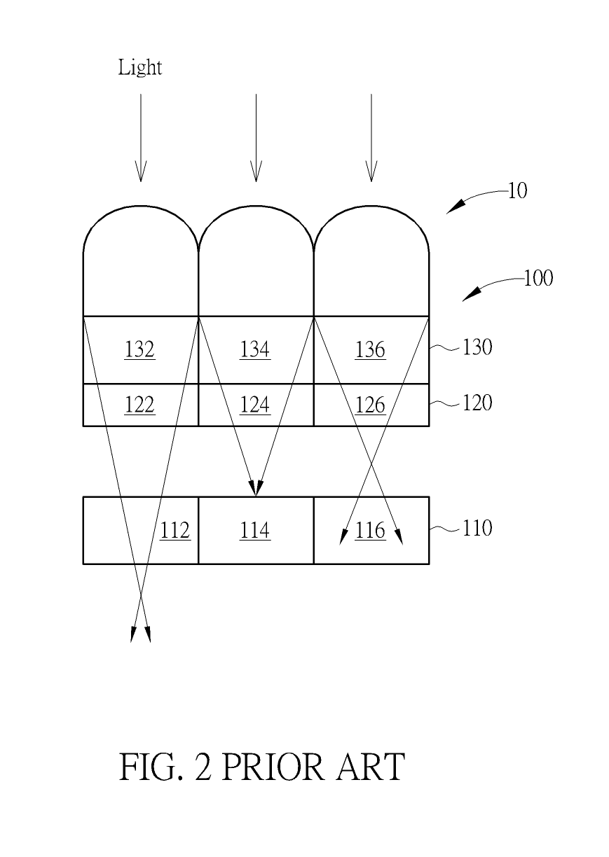

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

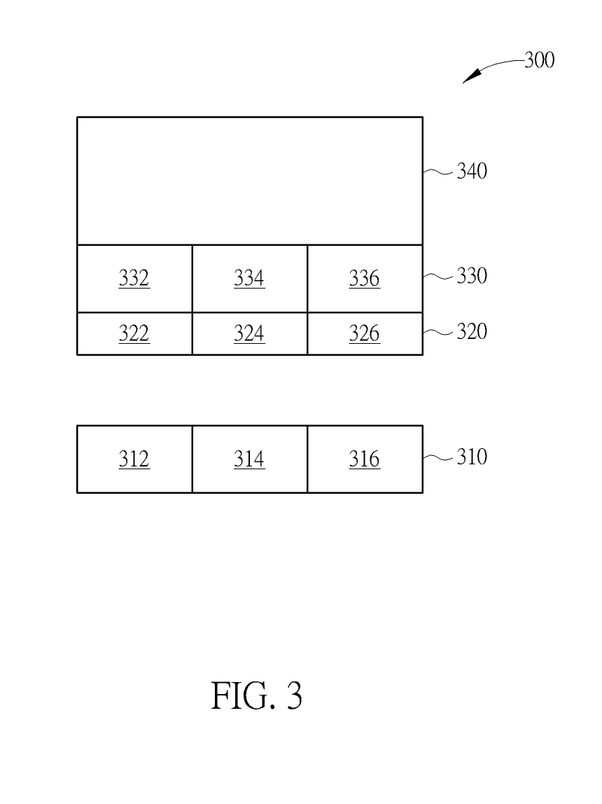

Please refer to FIGS. 3-7. FIGS. 3-7 are sectional diagrams illustrating sequential procedures of a method for fabricating a micro-lens array 200 with different heights in an image sensor 300 in accordance with an embodiment of the present invention, wherein the image sensor 300 comprises a photodiode array 310, a pixel array 320, and a color filter array 330. The pixel array 320 is disposed above the photodiode array 310, and each pixel of the pixel array 320 is corresponding to each photodiode of the photodiode array 310. The color filter array 330 is disposed above the pixel array 320, and has first color filters 332, second color filters 334, and third color filters 336 respectively corresponding to each pixel of the pixel array 320, wherein each first color filter 332 can be a red color filter, each second color filter 334 is can be a green color filter, and each third color filter 336 is can be a blue color filter. For example, as shown in FIG. 3, each of the first color filters 332 is corresponding to each pixel 322 of the pixel array 320 and each photodiode 312 of the photodiode array 310. Each of the second color filters 334 is corresponding to each pixel 324 of the pixel array 320 and each photodiode 314 of the photodiode array 310. Each of the third color filters 336 is corresponding to each pixel 326 of the pixel array 320 and each photodiode 316 of the photodiode array 310. In addition, a first step of the method in the present invention is forming a micro-lens material layer 340 on the color filter array 330 as shown in FIG. 3.

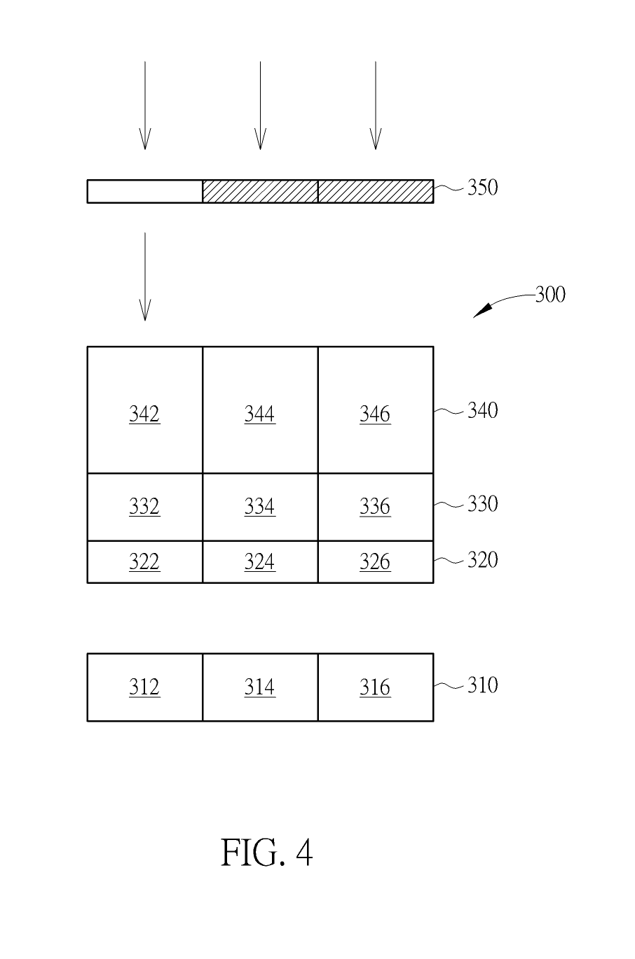

Next, as shown in FIG. 4, a second step of the method in the present invention is utilizing a first optical mask 350 to bleach the micro-lens material layer 340 corresponding to each first color filter 332 above each pixel 322 and each photodiode 312 in the image sensor 300. In addition, this step can comprise: exposing the micro-lens material layer 340 corresponding to each first color filter 332 (i.e. each unit 342 in the micro-lens material layer 340) through a first pattern of the first optical mask 350, wherein the first pattern prevents the micro-lens material layer 340 corresponding to each second color filter 334 and each third color filter 336 (i.e. each unit 344 and each unit 346 in the micro-lens material layer 340) from being exposed as shown in FIG. 4. For example, the present invention can provide a bleaching dose of 5500 J/m² for each unit 342 in the micro-lens material layer 340 via the first pattern of the first optical mask 350 and a light source of 365 nm.

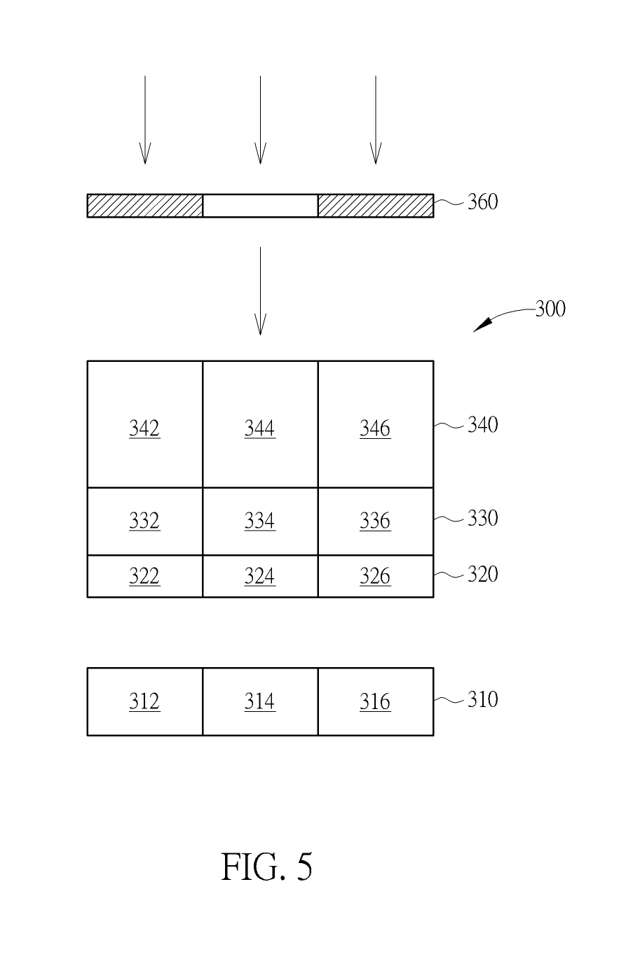

Next, as shown in FIG. 5, a third step of the method in the present invention is utilizing a second optical mask 360 to bleach the micro-lens material layer 340 corresponding to each second color filter 334 above each pixel 324 and each photodiode 314 in the image sensor 300. In addition, this step can comprise: exposing the micro-lens material layer 340 corresponding to each second color filter 334 (i.e. each unit 344 in the micro-lens material layer 340) through a second pattern of the second optical mask 360, wherein the second pattern prevents the micro-lens material layer 340 corresponding to each first color filter 332 and each third color filter 336 (i.e. each unit 342 and each unit 346 in the micro-lens material layer 340) from being exposed as shown in FIG. 5. For example, the present invention can provide a bleaching dose of 4000 J/m² for each unit 344 in the micro-lens material layer 340 via the second pattern of the second optical mask 360 and the light source of 365 nm.

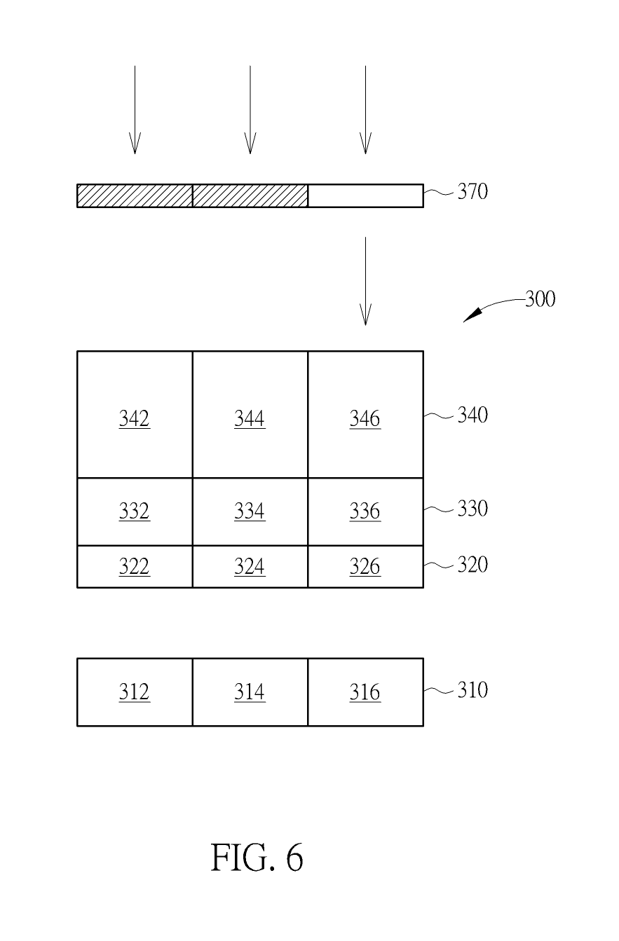

Next, as shown in FIG. 6, a fourth step of the method in the present invention is utilizing a third optical mask 370 to bleach the micro-lens material layer 340 corresponding to each third color filter 336 above each pixel 326 and each photodiode 316 in the image sensor 300. In addition, this step can comprise: exposing the micro-lens material layer 340 corresponding to each third color filter 336 (i.e. each unit 346 in the micro-lens material layer 340) through a third pattern of the third optical mask 370, wherein the third pattern prevents the micro-lens material layer 340 corresponding to each first color filter 332 and each second color filter 334 (i.e. each unit 342 and each unit 344 in the micro-lens material layer 340) from being exposed as shown in FIG. 6. For example, the present invention can provide a bleaching dose of 2000 J/m² for each unit 346 in the micro-lens material layer 340 via the second pattern of the third optical mask 370 and the light source of 365 nm.

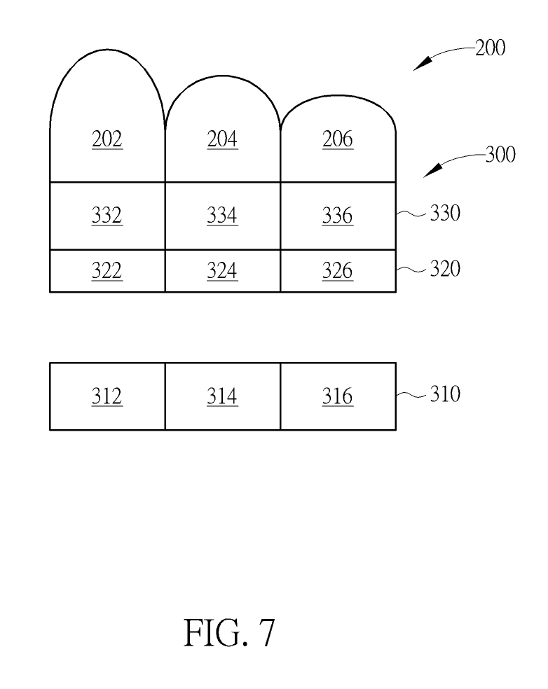

Next, as shown in FIG. 7, a fifth step of the method in the present invention is reflowing the bleached micro-lens material layer 340 to form the micro-lens array 200 having different heights. In addition, this step can comprise: forming the micro-lens array 200 to produce a first set of micro-lenses 202 having a first height corresponding to each first color filter 332, a second set of micro-lenses 204 having a second height corresponding to each second color filter 334, and a third set of micro-lenses 206 having a third height corresponding to each third color filter 336; wherein the first height is higher than the second height, and the second height is higher than the third height as shown in FIG. 7. Please note that the above embodiment is merely for an illustrative purpose and is not meant to be a limitation of the present invention. For example, the bleaching doses and the light source wavelength can be changed according to different design requirements, and thus the different heights of the micro-lens array 200 also can be changed accordingly.

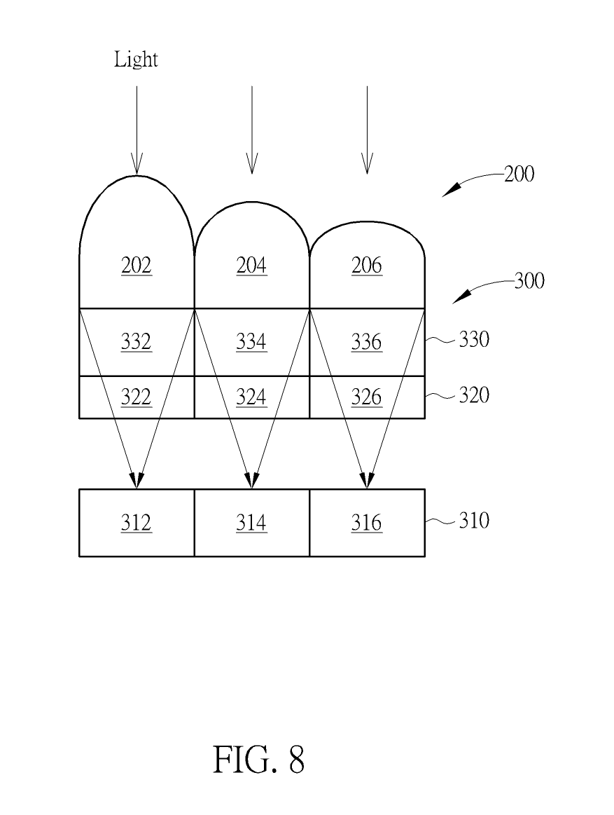

In this way, the first set of micro-lenses 202 and each first color filter 332 determine a first depth of focus for each photodiode 312 in the image sensor 300, and the second set of micro-lenses 204 and each second color filter 334 determine a second depth of focus for each photodiode 314 in the image sensor 300, the third set of micro-lenses and each third color filter determine a third depth of focus for each photodiode 316 in the image sensor 300, wherein the first depth of focus, the second depth of focus, and the third depth of focus are the same or very close to each other as shown in FIG. 8. Thus, the present invention can fabricate an image sensor 300 and a micro-lens array 200 with different heights in a pixel size level in the image sensor 300 to provide the same depth of focus (or nearly the same depth of focus) for every photodiode in the image sensor 300 with lower cost.

Briefly summarized, the present invention uses three different optical masks to fabricate a micro-lens array with different heights in a pixel size level in an image sensor, and the micro-lens array with different heights in a pixel size level in the image sensor disclosed by the present invention is capable of providing the same depth of focus (or nearly the same depth of focus) for every photodiode in the image sensor with lower cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a micro-lens array with different heights in an image sensor, wherein the image sensor has a color filter array comprising first color filters, second color filters, and third color filters respectively corresponding to each pixel and each photodiode of the image sensor, and the method comprises:
forming a micro-lens material layer on the color filter array;
utilizing a first optical mask to bleach the micro-lens material layer corresponding to each first color filter above each pixel of the image sensor;
utilizing a second optical mask to bleach the micro-lens material layer corresponding to each second color filter above each pixel of the image sensor;
utilizing a third optical mask to bleach the micro-lens material layer corresponding to each third color filter above each pixel of the image sensor; and
reflowing the bleached micro-lens material layer to form the micro-lens array having different heights.

2. The method of claim 1, wherein the step of utilizing a first optical mask to bleach the micro-lens material layer corresponding to each first color filter above each pixel of the image sensor comprises:
exposing the micro-lens material layer corresponding to each first color filter through a first pattern of the first optical mask, wherein the first pattern prevents the micro-lens material layer corresponding to each second color filter and each third color filter from being exposed.

3. The method of claim 1, wherein the step of utilizing a second optical mask to bleach the micro-lens material layer corresponding to each second color filter above each pixel of the image sensor comprises:
exposing the micro-lens material layer corresponding to each second color filter through a second pattern of the second optical mask, wherein the second pattern prevents the micro-lens material layer corresponding to each first color filter and each third color filter from being exposed.

4. The method of claim 1, wherein the step of utilizing a third optical mask to bleach the micro-lens material layer corresponding to each third color filter above each pixel of the image sensor comprises:
exposing the micro-lens material layer corresponding to each third color filter through a third pattern of the third optical mask, wherein the third pattern prevents the micro-lens material layer corresponding to each first color filter and each second color filter from being exposed.

5. The method of claim 1, wherein the step of reflowing the bleached micro-lens material layer to form the micro-lens array having different heights comprises:
forming the micro-lens array to produce a first set of micro-lenses having a first height corresponding to each first color filter, a second set of micro-lenses having a second height corresponding to each second color filter, and a third set of micro-lenses having a third height corresponding to each third color filter; wherein the first height is higher than the second height, and the second height is higher than the third height.

6. The method of claim 1, wherein each first color filter is a red color filter, each second color filter is a green color filter, and each third color filter is a red color filter.

7. A micro-lens array with different heights in an image sensor, wherein the image sensor has a color filter array comprising first color filters, second color filters, and third color filters respectively corresponding to each pixel and each photodiode of the image sensor, and the micro-lens array comprises:
a first set of micro-lenses, having a first adjustable height corresponding to each first color filter in a pixel size level;
a second set of micro-lenses, having a second adjustable height corresponding to each second color filter in the pixel size level; and
a third set of micro-lenses, having a third adjustable height corresponding to each third color filter in the pixel size level;
wherein the first adjustable height is higher than the second adjustable height, and the second adjustable height is higher than the third adjustable height.

8. The micro-lens array of claim 7, wherein each first color filter is a red color filter, each second color filter is a green color filter, and each third color filter is a blue color filter.

9. The micro-lens array of claim 7, wherein the first set of micro-lenses and each first color filter determine a first depth of focus, the second set of micro-lenses and each second color filter determine a second depth of focus, the third set of micro-lenses and each third color filter determine a third depth of focus, and the first depth of focus, the second depth of focus, and the third depth of focus are the same or very close to each other.

10. An image sensor, comprising:
a photodiode array;
a pixel array, disposed above the photodiode array, each pixel of the pixel array corresponding to each photodiode of the photodiode array;
a color filter array, disposed above the pixel array, having a first color filters, second color filters, and third color filters respectively corresponding to each pixel of the pixel array; and
a micro-lens array, disposed above the color filter array, comprising:
a first set of micro-lenses, having a first height corresponding to each first color filter in a pixel size level;
a second set of micro-lenses having a second height corresponding to each second color filter in the pixel size level; and
a third set of micro-lenses having a third height corresponding to each third color filter in the pixel size level;
wherein the first height is higher than the second height, and the second height is higher than the third height.

11. The micro-lens array of claim 10, wherein each first color filter is a red color filter, each first color filter is a green color filter, and each first blue filter is a blue color filter.

12. The micro-lens array of claim 10, wherein the first set of micro-lenses and each first color filter determine a first depth of focus, the second set of micro-lenses and each second color filter determine a second depth of focus, the third set of micro-lenses and each third color filter determine a third depth of focus, and the first depth of focus, the second depth of focus, and the third depth of focus are the same or very close to each other.
